(19) United States
(12) Patent Application Publication
(10) Pub. No.: US 2008/0158022 A1
(43) Pub. Date: Jul. 3, 2008

(54) BINARY KEYPAD APPARATUS AND METHOD FOR PORTABLE TERMINAL

(75) Inventor: Jin-Seok PARK, Seoul (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/958,005

(22) Filed: Dec. 17, 2007

(30) Foreign Application Priority Data
Dec. 28, 2006 (KR) 2006-0136137

(51) Int. Cl. H03K 17/94; H03M 11/00

(52) U.S. Cl. 341/22

(57) ABSTRACT

In a binary keypad apparatus for a portable terminal, a power supply supplies a current, and one or more general keys receive the current from the power supply and output the received current. One or more general purpose input/output (I/O) pins receive the current and output binary values corresponding to the received current.

### PRIORITY

This application claims priority under 35 U.S.C. § 119 to an application filed in the Korean Intellectual Property Office on Dec. 28, 2006 and assigned Serial No. 2006-0136137, the contents of which are incorporated herein by reference.

### BACKGROUND OF THE INVENTION

1. Field of the Invention

The present invention generally relates to a binary keypad apparatus and method for a portable terminal, and in particular, to a binary keypad apparatus and method that can reduce the number of General Purpose Input/Output (GPIO) pins used in a keypad of a portable terminal.

2. Description of the Related Art

Recently, portable terminals such as a mobile communication terminal or a Personal Digital Assistant (PDA) are widely used, and their application range is very wide. For example, a portable terminal may provide a call function, a scheduling function, an image capture function, a moving picture photographing function using a built-in digital camera, a Digital Multimedia Broadcasting (DMB) service, a text editing function, a game function, a navigation function, a music play function, a Short Message Service (SMS), and a function of transmitting/receiving multimedia message with a photographed image or moving picture attached thereto. As more functions are added to the portable terminal, the number of keys provided in a keypad of the portable terminal increases.

FIGS. 1A and 1B are plan views illustrating two types of keypads for a portable terminal. Specifically, FIG. 1A is a plan view of a portable terminal having Navigation keys (Up/Down/Left/Right) and a 3×4 alphanumeric keypad, and FIG. 1B is a plan view of a portable terminal having a QWERTY keypad.

The QWERTY keypad of FIG. 1B is usually used in a keyboard of a personal computer, and it is frequently used in a keypad of a portable terminal according to user's demand.

An internal circuit of the keypad illustrated in FIG. 1A will be described below with reference to FIG. 2. FIG. 2 is a circuit diagram illustrating a key matrix circuit of a keypad in a conventional portable terminal.

Referring to FIG. 2, a key matrix circuit is embedded as a key input detector in a portable terminal. That is, the key matrix circuit detects various key input from a keypad of the portable terminal. The key matrix circuit includes a plurality of row feeder lines and a plurality of column feeder lines, which are connected to GPIO pins KEY_SEN0/ to KEY_SEN4/ and GPIO pins KEY_SEN6 to KEY_SEN11 of a terminal controller (such as an MSM chip), respectively.

The key matrix circuit of FIG. 2 is implemented using a grid type keypad structure. In this case, a plurality of GPIO pins are required as expressed in Equation (1):

n_keybutton=row(n1_{—}GPIOs)×column(n2_{—}GPIOs)

n_{—}GPIOs=n1_{—}GPIOs+n2_{—}GPIOs (1)

where n1_GPIOs is the number of GPIO pins in a row direction in the grid type keypad structure, n2_GPIOs is the number of GPIO pins in a column direction in the grid type keypad structure, n_keybutton is a total number of available keys in the keypad of the grid type keypad structure, and n_GPIOs is a total number of GPIO pins necessary for the keypad of the grid type keypad structure.

For example, the 20-key keypad needs at least nine GPIO pins.

As illustrated in FIG. 2, if the number of GPIO pins increases with increasing number of keys, the volume of the portable terminal increases and the number of GPIO pins supportable by a controller of the portable terminal is limited. Therefore, the increase in the number of the GPIO pins for the keypad leads to the decrease in the number of GPIO pins for other peripheral circuits. Consequently, the conventional keypad has drawbacks in the connection of other peripheral circuits to GPIO pins.

Therefore, there is a need for a keypad apparatus that can detect a plurality of key inputs using a small number of GPIO pins.

### SUMMARY OF THE INVENTION

Accordingly, an aspect of the present invention is to provide a binary keypad apparatus and method for a portable terminal.

Another aspect of the present invention is to provide a binary keypad apparatus and method for a portable terminal, which uses a small number of GPIO pins.

A further aspect of the present invention is to provide a binary keypad apparatus and method for a portable terminal, which uses a small number of GPIO pins to output a binary value.

According to one aspect of the present invention, a binary keypad apparatus for a portable terminal includes a power supply for supplying a current; one or more general keys for receiving the current from the power supply and outputting the received current; and one or more general purpose input/output (I/O) pins for receiving the current and outputting binary values corresponding to the received current.

### BRIEF DESCRIPTION OF THE DRAWINGS

The above and other aspects, features and advantages of the present invention will become more apparent from the following detailed description when taken in conjunction with the accompanying drawings in which:

FIGS. 1A and 1B are plan views illustrating two types of keypads for a portable terminal;

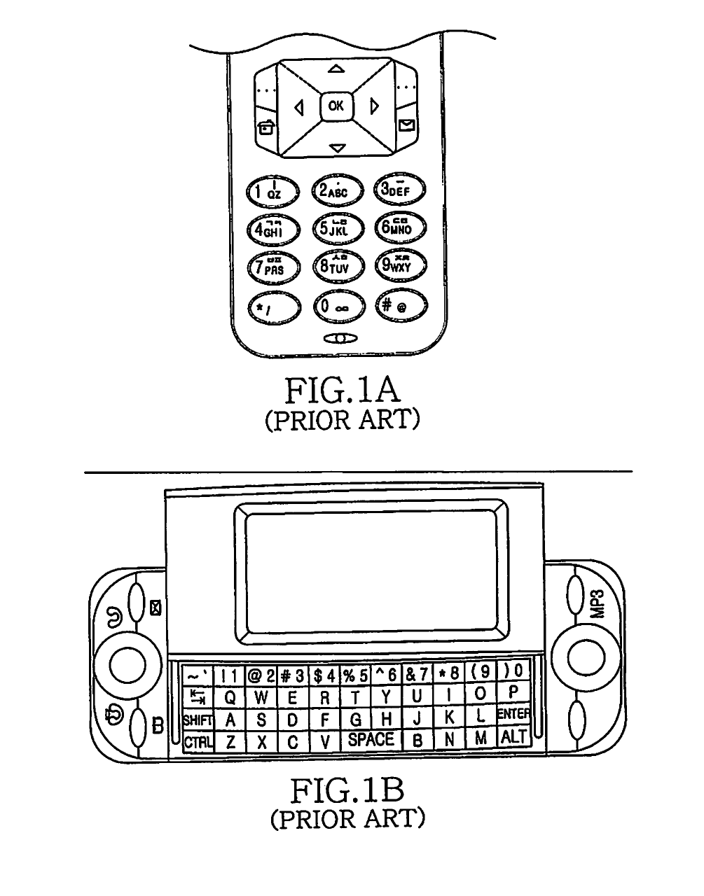

FIG. 2 is a circuit diagram illustrating a key matrix circuit of a keypad in a conventional portable terminal; and

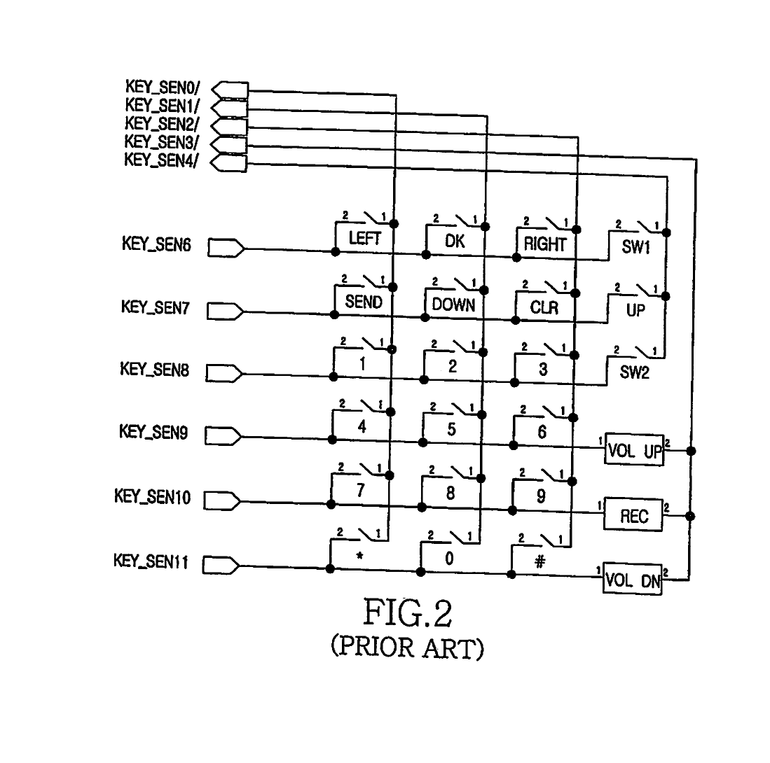

FIG. 3 is a circuit diagram illustrating a keypad of a portable terminal according to the present invention.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

A keypad apparatus according to the present invention includes a keypad circuit and GPIO pins, which are implemented to output a binary signal. Therefore, the number of GPIO pins can be reduced.

The phrase “output a binary signal” means that a numeral or character is expressed by a binary number “0” or “1”.

The number of numerals are expressed as Equation (2):

M=2^{N} (2)

where N is the number of binary bits representing binary digits, and M is the number of numerals that can be expressed with N bits.

As can be seen from Equation (2), if the binary output signal is applied to GPIO pins that can output two states, a plurality of key inputs can be provided using a small number of GPIO pins.

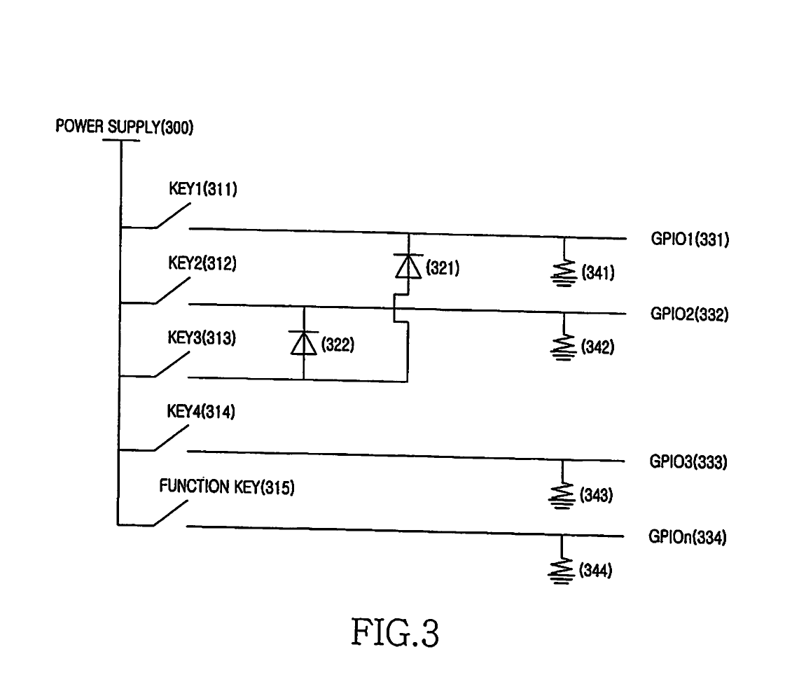

FIG. 3 is a circuit diagram illustrating a keypad of a portable terminal according to the present invention. Referring to FIG. 3, the keypad includes a power supply 300, four general keys 311 to 314, a function key 315, two diodes 321 and 322, four resistors 341 to 344, and GPIO pins 331 to 334.

The power supply 300 supplies a current to general keys 311 to 314 and function key 315.

General keys 311 to 314 acting as switches receive a current from the power supply 300. When a key input is detected, general keys 311 to 314 transfer the applied current to GPIO pins 331 to 334 using diodes 321 and 322. More specifically, binary values corresponding to the detected key inputs are transferred to GPIO pins 331 to 334.

Function key 315 is a key for detecting a key inputted simultaneously with general keys 311 and 314. GPIO pin 334 is separately provided to detect the input of function key 315 only.

GPIO pins 331 to 333 output binary values according to a current applied by the pressing of general keys 311 to 314. When function key 315 is pressed, a current passes through GPIO pin 334. That is, whether function key 315 is pressed can be determined by the current flowing through GPIO pin 334.

Meanwhile, currents applied at previous stages of GPIO pins 331 to 334 are grounded through resistors 341 to 344.

Binary outputs of the GPIO pins according to the key inputs in the circuit of FIG. 3 are listed in Table 1 below.

TABLE 1

| Results | Input key | GPIOn | GPIO3 | GPIO2 | GPIO1 |
|---|---|---|---|---|---|
| 1 | Key1 (311) input | 0 | 0 | 0 | 1 |
| 2 | Key2 (312) input | 0 | 0 | 1 | 0 |
| 3 | Key3 (313) input | 0 | 0 | 1 | 1 |
| 4 | Key4 (314) input | 0 | 1 | 0 | 0 |
| Shift | Function key (315) input | 1 | 0 | 0 | 0 |

In the keypad having the GPIO pins that output binary values, as the number of GPIO pins increases by one, the number of recognizable keys increases by a multiple of 2. For example, when three GPIO pins are allocated to keys of the keypad, eight key inputs are possible. When four GPIO pins are used, sixteen key inputs are possible.

The portable terminal with the above-described keypad stores a key table, e.g., Table 1. Hence, when the controller detects the output of GPIO pins 331 to 334, it can detect the corresponding key input using the stored key table.

As described above, a binary keypad apparatus for a portable terminal includes a power supply for supplying a current; one or more general keys for receiving the current from the power supply and outputting the received current; and one or more general purpose input/output (I/O) pins for receiving the current and outputting binary values corresponding to the received current.

Alternate embodiments of the present invention can also comprise computer readable codes on a computer readable medium. The computer readable medium includes any data storage device that can store data that can be read by a computer system. Examples of a computer readable medium include magnetic storage media (such as ROM, floppy disks, and hard disks, among others), optical recording media (such as CD-ROMs or DVDs), and storage mechanisms such as carrier waves (such as transmission through the Internet). The computer readable medium can also be distributed over network coupled computer systems so that the computer readable code is stored and executed in a distributed fashion. Also, functional programs, codes, and code segments for accomplishing the present invention can be construed by programmers of ordinary skill in the art to which the present invention pertains.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A binary keypad apparatus for a portable terminal, comprising:
a power supply;
at least one general key for receiving a current from the power supply and outputting the received current; and
at least one general purpose input/output (GPIO) pin for outputting binary values corresponding to the received current from the at least one general key.

2. The binary keypad apparatus of claim 1, further comprising:
a function key for receiving an other current from the power supply through the function key to detect a key inputted simultaneously with the at least one general key, and outputting the other current when the key input is detected; and
an other GPIO pin for transferring the other current.

3. The binary keypad apparatus of claim 2, wherein the other current is grounded through a resistor.

4. The binary keypad apparatus of claim 1, wherein the current through the at least one GPIO pin is grounded through at least one resistor.

5. The binary keypad apparatus of claim 1, wherein the number of the general keys according to the number of the GPIO pins is expressed as:
M=2^{N}
where N is the number of the GPIO pins, and M is the number of the general keys expressable with the N number of the GPIO pins.

6. A binary keypad apparatus for a portable terminal, comprising:
at least two keys for outputting a value signal; and
at least one general purpose input/output (GPIO) pin for outputting binary values corresponding to the value signal from the at least two keys.

7. The binary keypad apparatus of claim 6, further comprising:
a function key for outputting an other value signal for performing the function of the function key; and
an other GPIO pin for corresponding to the function key.

8. A binary keypad method for a portable terminal, comprising:
outputting a value signal by at least two keys; and
outputting binary values by at least one general purpose input/output (GPIO) pin corresponding to the value signal from the at least two keys.

9. The method of claim 8, further comprising;
outputting an other value signal for performing the function of a function key.

10. A computer-readable recording medium having recorded thereon a program for a binary keypad method in a portable terminal, comprising:
a first code segment for outputting a value signal by at least two keys; and
a second code segment for outputting binary values by at least one general purpose input/output (GPIO) pin corresponding to the value signal from the at least two keys.
